(19) United States
(12) Patent Application Publication
(10) Pub. No.: US 2011/0263073 A1
(43) Pub. Date: Oct. 27, 2011

(54) Physical Vapour Deposition Processes

(76) Inventors: Kenneth Durose, Durham (GB); Jon Major, Liverpool (GB)

(21) Appl. No.: 12/994,849

(22) PCT Filed: May 25, 2009
(86) PCT No.: PCT/GB09/50562

§ 371 Date: Jul. 12, 2011

(30) Foreign Application Priority Data
May 27, 2008 (GB) 0809530.9

(51) Int. Cl. H01L 31/18; C23C 16/455; C23C 16/44

(52) U.S. Cl. 438/95; 427/248.1; 427/255.23; 257/E31.015

(57) ABSTRACT

A method of depositing a film of a first material, such as Cadmium Telluride on to a second material, such as Cadmium Sulphide by a physical vapour deposition process wherein said deposition is performed in an atmosphere having a relatively high ambient pressure, in one embodiment between 50 and 200 Torr.

This invention relates to improved physical vapour deposition processes, and in particular to methods that result in the material being deposited having a large grain structure.

Physical vapour deposition (PVD) is a general term used to describe any of a variety of methods to deposit thin films by the condensation of a vaporized form of the material onto various surfaces (e.g., onto semiconductor wafers). The coating method involves purely physical processes such as high temperature vacuum evaporation, sublimation transfer from a hot source to a cooler substrate, or plasma sputter bombardment rather than involving a chemical reaction at the surface to be coated as in chemical vapor deposition.

The microstructural properties of a thin film will be dependant upon the processes that govern its formation and may be very different from that of the bulk material. The early stages of film formation, nucleation and growth up to the point of coverage of the substrate, are of particular importance. Use of different temperatures, pressures or impurities may alter the early growth mechanism and produce films of differing quality.

One application of the above techniques is to deposit CdTe onto a layer of CdS (Cadmium Sulphide). Many methods have been reported in the literature including sublimation and its variants as mentioned above. A variant of PVD, where the source is contained in a tray, and the substrate is in close proximity to it, is known as close space sublimation (CSS). CSS itself is used by some manufacturers of solar cells, and variants by others. Laboratory variations include Hot Wall Close Space Vapour Transport.

Thin film solar cells made from the semiconductor CdTe (cadmium telluride) have been known in the literature for many years, but are emerging now as a production technology in both the USA and in Europe.

Thin films of comprising a polycrystalline material (such as cadmium telluride-CdTe) consist of small crystallites with a variety of orientations. The regions between adjoining crystallites are known as grain boundaries and may have a significant impact upon the photovoltaic performance of CdTe/CdS devices. There is expected to be a high defect density (e.g. dangling bonds, lattice dislocations) at the grain boundaries, as well as the possible segregation of impurities there. The grain boundaries therefore act as strong recombination centres, due to the introduction of deep energy levels within the bandgap resulting from the high defect concentration. Grain boundaries may also act as barriers to current transport or cause significant leakage current owing to low resistance paths forming as a result of the granular structure.

In view of the above, it is desirable to have large-grained material. In the context of solar cells, this is to
a) reduce chemical diffusion along grain boundaries. This is expected to be deleterious to the stability of the devices
b) to lower the barriers to electronic carrier transport within the devices. Grain boundaries are thought to be associated with electronic barriers. Increasing the grain size reduces the density of such barriers.
c) to lower the extent of recombination of charge carriers at the grain boundaries. The electrons and holes that are excited by light in a solar cell are expected to be recombined more rapidly at grain boundaries than in the bulk. Reduction of the density of grain boundaries might be expected to reduce such losses.

Consequently, it is an aim of the invention to provide a method to increase the grain size above what is normally obtained using physical vapour deposition, and in particular, CSS growth of CdTe.

In a first aspect of the invention there is provided a method of depositing a film of a first material on to a second material by a physical vapour deposition process wherein said deposition is performed in an atmosphere having a relatively high ambient pressure.

Physical vapour deposition is to be taken in its widest sense to include any deposition process whereby a source material is first evaporated and then deposited on a substrate. Relatively high ambient pressure should be taken to mean relatively high with regard to conventional physical vapour deposition techniques, which are conventionally carried out in high vacuums.

Said relatively high pressure may be 20 Torr or more. Experiments show good results at pressures over 50 Torr, and in particular at orders of magnitude of 100 Torr. Although the inventors' experiments suggest that even greater pressures should result in even larger grain sizes, deposition growth time also increases with the atmosphere pressure, and therefore a range between 50 Torr and 200 Torr is considered a practical pressure range for commercial processes.

Said physical vapour deposition process may be any such growth mechanism based on sublimation transfer, such as close-space sublimation.

Said atmosphere may comprise a substantially pure inert gas. Said gas may be Nitrogen. Alternatively, said gas may be a gas of lower molecular weight to increase deposition speed. This gas may, for example, be hydrogen, helium, or a mixture of either (or both) with nitrogen.

Said method may take place in a deposition chamber, said relatively high ambient pressure, being the pressure in said deposition chamber.

Said first material may be a semiconductor material, for example Silicon, Gallium arsenide or any other of the group III-IV semiconductors, or Cadmium Telluride or any other of the group II-VI semiconductors. Said method may be used in the manufacture of solar cells. In this case said first material may be Cadmium Telluride and said second material may be Cadmium Sulphide.

Said method may include varying the ambient pressure during the deposition process. In particular said method may be begun at said relatively high ambient pressure to nucleate large grains, the pressure being subsequently lowered to speed up deposition. Said lowering of pressure may happen once, a plurality of times in a stepwise fashion, or continuously lowered in a ramped fashion. In the latter two cases, said lowering of the pressure may be done throughout the deposition process, or during a portion of it. In particular, it may begin only after a predetermined interval. Said lowering of the pressure may be achieved, for example, by pumping, or by moving the sample through more than one space or chamber, each of which having different ambient pressures.

### BRIEF DESCRIPTION OF THE DRAWINGS

Embodiments of the invention will now be described, by way of example only, by reference to the accompanying drawings, in which:

FIG. 1 shows a CdTe/CdS solar cell and in particular its superstrate geometry;

FIG. 2 depicts the three well known distinct modes of thin film crystal growth;

FIG. 3 illustrates a typical sequence of distinct stages that occur during polycrystalline thin film growth;

FIG. 4 shows the equilibrium surface forces and contact wetting angle for a spherical cap;

FIG. 5 shows the addition, diffusion and binding of adatoms to a step producing the phenomenon of step flow, b) the formation of a smooth crystal facet by uninterrupted step flow;

FIG. 6 show AFM images of CdTe thin films deposited on CdS under 200 Torr of nitrogen for growth times between 5 and 360 min;

FIG. 7 are histograms showing Island width for various growth times;

FIG. 8 are graphs showing schematic island size distributions for: a) coalescence by island mobility, b) coalescence by island growth;

FIG. 9 shows SEM images of CdTe layers deposited under different pressures of nitrogen;

FIG. 10 is a graph showing average grain diameter for CdTe layers deposited under different nitrogen pressure;

FIG. 11 shows grain diameter histograms (100 grains) for CdTe layers deposited under different nitrogen pressures;

FIG. 12 shows AFM images of CdTe layers deposited under different pressures of nitrogen;

FIG. 13 are J-V curves recorded under AM1.5 illumination for cells with CdTe layers deposited under 2 Torr and 100 Torr of nitrogen;

FIG. 14 is a plurality of graphs showing average device performance parameters extracted from J-V curves as a function of nitrogen deposition pressure;

FIG. 15 shows the same graphs as FIG. 14 plotted as a function of grain size.

FIG. 16 shows normalised EQE curves for devices with CdTe layers grown under various pressures of nitrogen;

FIG. 17 shows an equivalent circuit model for the solar cell used to extract the components of resistance considered to influence the device performance; and

FIG. 18 is a graph showing grain boundary resistance component vs grain size determined from ac measurements of solar cell devices.

### DETAILED DESCRIPTION OF THE EMBODIMENTS

While it is to be understood that the invention disclosed herein is applicable to any physical vapour transfer mechanism or essentially where any solid is sublimated onto another, the following discussion will be made with reference to the formation of Cadmium Telluride (CdTe) semiconductor devices, and in particular to CdTe used in combination with Cadmium Sulphide (CdS) as a hetero-junction partner, which has become the standard arrangement for CdTe based devices. Owing to its near ideal bandgap and high optical absorption coefficient, CdTe is seen as a highly suited absorber layer for solar cells.

FIG. 1 shows a CdTe/CdS solar cell and in particular its superstrate geometry. In this arrangement all deposition takes pace on a glass substrate, which then becomes the front surface in the completed device. Although CdTe/CdS devices are sometimes prepared in the substrate configuration (where the deposition substrate becomes the device back surface) the superstrate configuration is by far the most common device geometry encountered.

The fabrication of a superstrate CdTe/CdS solar cell may be briefly summarised as follows:
I. A transparent conducting oxide (TCO) layer 100 is deposited onto a glass substrate 105 to act as the front contact to the device.
II. A CdS window layer 110 is then deposited onto the TCO/glass structure.
III. The CdTe absorber layer 115 is deposited onto the CdS layer leading to the formation of the p-CdTe/n-CdS junction.
IV. The CdTe/CdS/TCO/glass structure is then subjected to a cadmium chloride (CdCl₂) “activation” step. A thin (typically 50-200 nm) CdCl₂ layer 115 is deposited onto the CdTe back surface, before the entire structure is annealed.
V. The CdTe layer is etched to provide a suitable surface for the back contact to be applied.
VI. A back contact 120 is applied to the device.

As explained in the introduction, it is advantageous to device performance to minimise the impact of grain boundaries by maximising the grain size of CdTe films. It is known that the grain size of CdTe films strongly depends on the deposition temperature, with the largest grained films usually being produced by high temperature deposition methods, particularly close space sublimation (CSS). The majority of high efficiency devices reported typically utilise CdTe layers deposited by CSS although good quality CdTe layers are also deposited by a number of methods such as pulsed laser deposition, MOCVD, sputtering, screen printing and electrodeposition.

In the following examples CdTe layers have principally been deposited by the CSS technique.

Key requirements of CdTe layer for good quality devices:
Strong p-type character
Large grain size
Continuous film (no pinholes)

Thin Film Growth Modes

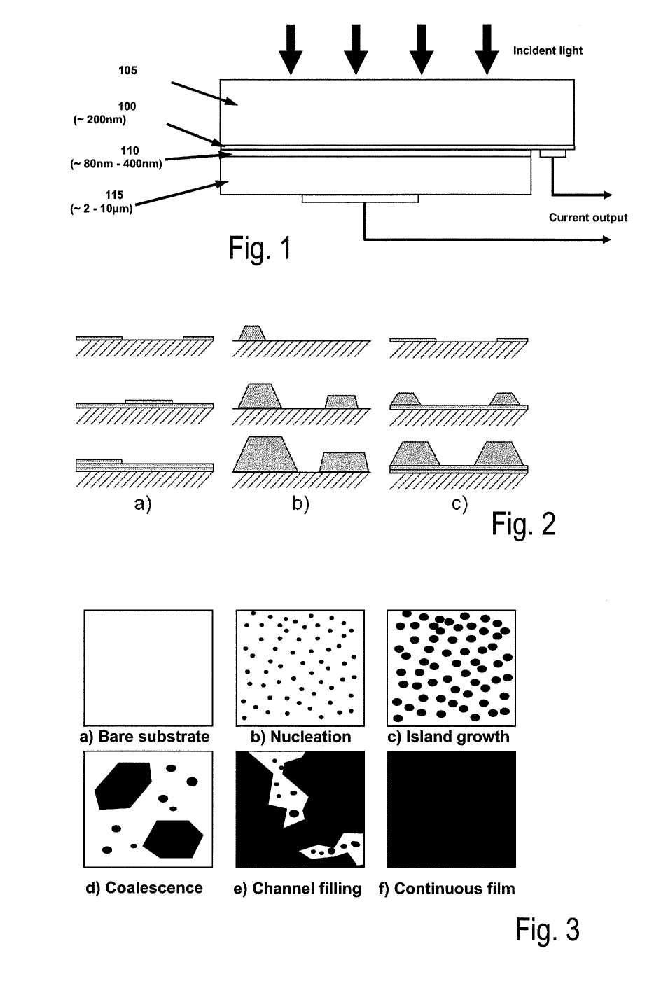

Firstly, the basics of thin film crystal growth will be explained. The three well known distinct modes of thin film crystal growth are shown in FIG. 2. The mode by which a given material will grow is dependent on the difference in chemical potentials between film-film and film-substrate atomic interactions. Each growth mode will now be discussed in turn.

Frank-Van Der Merwe Growth

Layer-by-layer' or Frank- van der Merwe growth (FIG. 2a) occurs when the binding energy between an atom and the surface is greater than that between individual atoms within a layer. In this case nucleation is two dimensional, leading to the formation of planar sheets. After formation of a complete monolayer, a second less tightly bound monolayer forms on top. The ‘layer-by-layer’ growth mode will be sustained providing the decrease in binding energy with thickness is continuous and approaches toward the bulk crystal value of the deposited material.

Volmer-Weber Growth

In the ‘island’ or Volmer-Weber growth mode (FIG. 2b), the binding energy between adatoms is stronger than their binding to the surface. In this case three dimensional clusters nucleate on the surface and grow to form island structures. A wide range of thin film systems display this growth mode including CdTe/GaAs, NiTi/Silicon nitride and Cu/Si. The Volmer-Weber mechanism is assumed to be the principal growth mode of most polycrystalline thin films.

Stranski-Krastanov Growth

An intermediate case between the ‘layer-by-layer’ and ‘island’ growth modes is the Stranski-Krastanov mode (FIG. 2c). After an initial number of monolayers have formed the monotonic decrease in binding energy (a requirement for ‘layer-by-layer’ growth to be sustained) is interrupted. Island growth then takes place on top of the monolayers leading to the layer-plus-island' structure. The onset of Stranski-Krastanov growth is usually ascribed to the accumulation of strain in the growing film due to film-substrate lattice mismatch. Energy deposited at the surface when this strain is released triggers the island formation.

In the examples considered below, it can be demonstrated that growth proceeds by the ‘island’ mechanism. Accordingly the detailed descriptions of film formation that now follow are centred on the Volmer-Weber mechanism of nucleation and the processes that follow it in order to form a complete film.

Film Formation Processes

Polycrystalline thin film growth via the ‘island’ (Volmer-Weber) mechanism may be divided into three stages, i) nucleation, ii) early and iii) late stages of growth that collectively lead to the formation of a complete film. FIG. 3 illustrates a typical sequence of distinct stages that occur during polycrystalline thin film growth from the vapour-which proceeds as follows: Firstly, an initial set of nuclei is formed on the surface by deposition from the vapour (FIG. 3b) Those nuclei that are stable (to re-evaporation) continue to grow by addition of material from the vapour and by surface diffusion of adatoms. The islands become enlarged, but the distribution remains unchanged as no further nucleation occurs at this stage (FIG. 3c). As these islands continue to grow they come into contact with one-another and coalescence processes begin to occur (FIG. 3d). During this period further nucleation is assumed not to occur, since established islands capture, and incorporate, the majority of adatoms incident upon the surface. When islands reach a certain size they no longer completely coalesce and re-order, due to the slow rate at which the process occurs for larger islands. A network of interconnected islands, with empty channels in-between, is then formed (FIG. 3e). Secondary nucleation now becomes possible in the channels, as areas that were previously occupied by islands (or their associated capture zones) has been revealed due to the reduction in coverage resulting from coalescence of primary islands. Following this, a continuous thin film with no gaps will eventually be formed by coalescence of secondary nuclei, and their incorporation into the channel walls (FIG. 3f).

Nucleation of Thin Films

The formation of three dimensional nuclei on a surface is considered the starting point of Volmer-Weber thin film growth, the nuclei being small clusters of material condensed on the surface. The relative size and distribution of nuclei formed at this early stage will be influenced by factors such as the temperature and deposition rate. The following outlines the thermodynamic and atomistic principles related to the formation of nuclei.

Condensation and the Driving Force for Nucleation

In the case of close spaced sublimation, nucleation takes place via a vapour—solid phase transition. The thermodynamic driving force behind this, and the subsequent occurrence of nucleation, is the change in the Gibbs free energy of the system ΔG, during this phase transition;

ΔG=G_{Final}−G_{Initial} (0.1)

where G_{Final} and Gᵢₙᵢₜᵢₐₗ are the Gibbs free energies of the system in its final and initial states respectively. Nucleation occurs when ΔG<0, i.e. when the free energy of the system is reduced by condensation from the vapour into the solid phase. A positive value for the change in free energy will mean nucleation is unfavourable and will therefore not occur under such conditions.

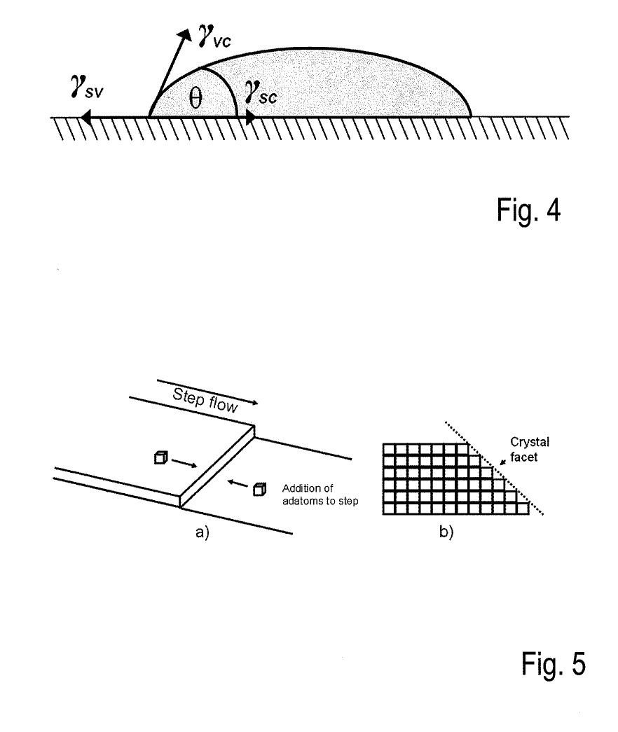

The capillarity, or droplet model of nucleation assumes that nuclei take the form of a spherical cap as shown in FIG. 4. Whilst solidified nuclei often have crystallographic forms, the spherical cap model provides a reasonable approximation with convenient geometries. If a droplet, of radius r, forms on the surface after condensing from the vapour phase, the associated change in Gibbs free energy is given by;

ΔG=a₁r²γ_{VC}+a₂r²γ_{SC}−a₂r²γ_{SV}+a₃r³ΔG_{V} (0.2)

where aᵢ terms are geometrical constants. a₁r² is the surface area of the condensate in contact with the vapour and γ_{VC} is the free energy for the formation of the surface between the vapour and condensate. a₂r² is the contact area between the condensate and substrate with γ_{SC} the free energy of the surface between the substrate and the condensate. The term a₂r²γ_{SV} accounts for the reduction in substrate area in contact with the vapour as a result of the condensate forming, where γ_{SV} is the associated surface-vapour free energy term, a₃r³ is the volume of the condensate and ΔG_{V} is the change in free energy of condensation defined as;

$$Δ {G}_{V} = - \frac{kT}{V} ln \frac{p}{{p}_{e}} \qquad ( 0.3 )$$

where k is Boltzmann's constant, V is the volume of an adatom of deposited material, T is the temperature, p is the vapour pressure and pₑ is the equilibrium vapour pressure. The term (p/pₑ) is known as the supersaturation ratio, S. In order for nucleation to occur ΔG_{V} must be <0. The supersaturation ratio must therefore be >1 with the vapour pressure greater than the equilibrium pressure and ‘saturated’ in order for nucleation to occur.

Equation 0.2 may be simplified if it is assumed that the aggregate has a spherical shape. In this case the equation 0.2 becomes;

$$Δ G = 4 π {r}^{2} {γ}_{VC} + \frac{4}{3} π {r}^{3} Δ {G}_{V} \qquad ( 0.4 )$$

It can be shown that there is a maximum value for the change in free energy at a particular radius, know as the critical radius, r*.

This critical radius is the lower limit of size that a nucleus must attain to be stable. Small aggregates of a size <r* will experience an increase in their free energy as they grow. This means that as further material adds to the nucleus it remains susceptible to evaporation. For nuclei of radius >r* the free energy will decrease with growth and hence may be considered as stable clusters. The value of r* will be the value at which;

$$\frac{\partial ( Δ G )}{\partial r} = 0 \qquad ( 0.5 )$$

Differentiating equation 0.4 gives;

$$\frac{\partial Δ G}{d r} = 4 π {r}^{2} Δ {G}_{V} + 8 π r {γ}_{VC} = 0 \qquad ( 0.6 )$$

Re-arranging equation 0.6 for r and substituting in equation 0.3 gives;

$${r}^{*} = \frac{2 {γ}_{VC} V}{kT ln ( \frac{p}{{p}_{e}} )} \qquad ( 0.7 )$$

It may be seen from equation 0.7 that the critical radius is principally dependant upon the temperature and supersaturation ratio, as all other terms are constant for a given material. At constant temperature an increase in the supersaturation ratio (which will increase the deposition rate of material onto the surface) will reduce the size of the critical nucleus. The temperature dependence of r* is not as simple to discern. From equation 0.7 it may appear that if temperature is increased that the value of r* will decrease. However, the equilibrium vapour pressure, pₑ, is dependant upon temperature and as a consequence the supersaturation ratio is also temperature dependant. The equilibrium vapour pressure of a liquid may be related to temperature via the Clausius-Clapeyron relation (see for example Sears);

$${p}_{e} = A exp ( \frac{- Δ {H}_{vap}}{RT} ) \qquad ( 0.8 )$$

where ΔHᵥₐₚ is the change in molar enthalpy for vaporisation, R is the gas constant and A is a constant. Equation 0.8 shows that the equilibrium vapour pressure increases exponentially with temperature, leading to an exponential decrease in the supersaturation ratio. The term, In(p/pₑ), in equation 0.7 therefore decreases at a greater rate than the associated increase in T and increasing the temperature therefore increases the size of the critical radius.

In the case of polycrystalline thin films, the grain structure in the completed film will be determined in part by the initial distribution of nuclei formed on the surface. Under conditions where each nucleus develops to form a single grain, achieving control of the nucleation density may be expected to give direct control of the grain size. In conditions where the nucleation density is not constant throughout growth, the initial density will still play an important role in determining grain structure as it provides an initial template for growth. The critical radius and its dependence on factors such as temperature and supersaturation ratio, may in part determine the nucleation density. In conditions that define a relatively large critical radius (e.g. high temperature), the probability of a stable nucleus forming is small and as a result the density of nuclei on the surface will be low. As the critical radius is reduced, the formation of stable nuclei becomes increasingly likely and the nucleation density will be increased. Therefore, it is possible that control of grain size in the completed film may be achieved by manipulation of the critical radius.

While the background for the above argument is presented for the case of homogenous nucleation in the vapour phase, analogous outcomes are expected for heterogeneous nucleation.

Nuclei will make a given angle with the surface, dependent on upon the surface forces acting upon it as illustrated in FIG. 4. This is known as the contact or wetting angle θ. In the instance of strong attraction between atoms of the deposited material, the contact angle will be high as atoms will bunch together and from 3-D nuclei. In the case of strong film-substrate attraction, the deposit will instead spread across the surface with a small contact angle. γ_{VC}, γ_{SC} and γ_{SV} were defined above as the surface free energies between the surface, condensate and vapour for the purpose of free energy calculations. These terms may also be considered as the respective interfacial tensions between the surface, condensate and vapour. These tensions determine the contact wetting angle by the relation;

$$Cos θ = \frac{{γ}_{SV} - {γ}_{SC}}{{γ}_{VC}} \qquad ( 0.9 )$$

In the case of ‘layer-by-layer’ growth the contact wetting angle is assumed to be zero and the nucleus will be a flattened disk. Here the deposit ‘wets’ the surface and the surface-vapour tension is balanced by the surface-condensate and vapour-condensate tensions as follows:

γ_{SV}=γ_{SC}+γ_{VC} (0.10)

For island growth the wetting angle will be finite (θ>0) and the surface-vapour tension will be less than the combination of the surface-condensate and vapour-condensate tensions;

γ_{SV}<γ_{SC}+γ_{VC} (0.11)

In Stranski-Krastanov growth the value of θ changes during growth. After initially being zero, with growth progressing by ‘layer-by-layer’, the angle will become finite after deposition of a number of monolayers. Island growth will then begin on top of a continuous layer.

In order to better understand the mechanics of thin film growth the various processes encountered by species on the surface are considered from an atomistic standpoint When atoms or molecules condense onto the surface from the vapour phase they are termed adatoms, this being synonymous with ‘adsorbed monomers’ or ‘surface species’. Once on the surface, adatoms are assumed to migrate across it by surface diffusion. Following this an adatom may bind with other adatoms on the surface, bind at a kink or step site, undergo capture and be incorporated by an existing nucleus, or simply re-evaporate from the surface. The rate and frequency with which these interactions occur will be dependant not only upon the nature of the surface and deposited material, but also by the conditions under which material is deposited.

Nucleation from an atomistic viewpoint may be treated as a series of collisions, migrations and binding events between adatoms on the surface. From thermodynamic theory it is known that clusters need to attain the critical radius before being stable and no longer prone to re-evaporation. The formation of a stable nucleus will therefore require a certain number of adatom-adatom collisions to occur, with a larger critical radius increasing the number of collisions required. For example, higher substrate temperature will increase the size of the critical radius and will thus increase number of adatom collisions required to form a stable nucleus. As the number of required adatom collisions increases the probability of a stable nucleus being formed is thereby reduced. However, once a nucleus of a super-critical size is achieved it is assumed to remain on the surface and will continue to grow into an island structure, principally by capture of further adatoms diffusing across the surface.

An important parameter to be considered during nucleation is the number of adatoms on the surface at a given time, n₁(t). For a surface assumed to have a fixed number, n₀, of sites available, this leads to a surface occupancy of (n₁/n₀). The probability of surface collisions occurring, hence leading to successful nucleation, will be increased by a greater number of species being present on the surface at any given time. Therefore by controlling the arrival and re-evaporation rates of adatoms on the surface, the nucleation dynamics of the growing film may be controlled. Lower adatom surface concentrations will reduce the number of nuclei formed, due to the decreased probability of collisions occurring. Nuclei formed at low surface concentrations may therefore be expected grow to larger island sizes than those formed at high concentrations, due to a greater fraction of adatoms resident on the surface being collected by each island. Assuming the number of surface sites available is constant for a given surface, the surface occupancy is determined by the population of adatoms on the surface. The value of n₁ will depend on the rate adatoms impinge onto the surface, and how long they remain adsorbed before re-evaporating from it, or being incorporated into a cluster. Adatoms arrive at the surface at a constant rate, R, and will also leave the surface via re-evaporation at a given rate. We may therefore ascribe an average lifetime for an adatom on the surface, τₛ, during which time the adatom will diffuse across the surface and either collide with another monomer or re-evaporate. The number of adatoms on the surface may be related to the arrival rate and the average monomer lifetime by;

n₁=Rτₛ (0.12)

From equation 0.12 it can be seen that a lower arrival rate or shorter lifetime will reduce the species surface concentration. Conditions resulting in lowering either of these parameters may therefore be expected to lower the nucleation density while higher values will increase the probability of the formation of stable nuclei. The rate of arrival of adatoms onto a surface may be altered by numerous factors that are normally specific to the deposition system being employed (e.g. factors affecting the rate of species arrival in electro-deposition will not be applicable to vacuum evaporation). In the case of CSS the arrival rate may be affected by source-substrate geometry, source temperature and inert gas pressure in the reactor.

The average adatom lifetime for a given materials system is determined principally by the temperature of the substrate. While the manner of deposition may still change the adatom lifetime, substrate temperature is important in most growth systems and the impact of changing the adatom lifetime on growth is therefore more general applicable. The average lifetime of an adatom on the surface before re-evaporation, τₛ, is given by;

$${τ}_{S} = \frac{1}{v} exp ( \frac{{E}_{a}}{{kT}_{sub}} ) \qquad ( 0.13 )$$

Where T_{sub} is the temperature of the substrate, Eₐ is the energy required for re-evaporation from the surface and v is the vibrational frequency of an adatom on the surface. Variation of τₛ will also affect the diffusion of adatoms on the surface as adatoms that remain on the surface for a longer time will be able to diffuse a greater distance. However at higher substrate temperatures adatoms will have higher mobility on the surface. The mean diffusion distance of an adatom, X, can be related to the lifetime via;

X=\sqrt{2Dₛτₛ} (0.14)

Where;

$${D}_{S} = ( 1 / 2 ) {a}_{0}^{2} v exp - ( \frac{{E}_{d}}{{kT}_{sub}} ) \qquad ( 0.15 )$$

D_{S} is the surface diffusion coefficient, E_{d} is a constant, E_{d} is the activation energy for diffusion and therefore;

$$X = {a}_{0} exp ( \frac{{E}_{a} - {E}_{d}}{2 {kT}_{sub}} ) \qquad ( 0.16 )$$

As Eₐ, E_{d} and v are properties of the surface and the deposited material it can be seen from equations 0.13 and 0.16 that the principle experimental control over the lifetime and diffusion of adatoms, for a given material system, comes from variation of the substrate temperature. Increasing the substrate temperature will decrease the average lifetime of an adatom on the substrate and decrease the surface occupancy (n₁/n₀). In this instance nucleation becomes less likely due to the reduction in probability of adatom collisions and the density of nuclei formed will be reduced.

On a perfect surface, nucleation will only occur due to adatom collisions. However, on a real surface nucleation may also occur at as kink or step sites on the surface. These are defects in the surface and offer preferred binding sites since they provide a higher number of nearest neighbour bonds to an adatom than on a planar surface: an atom absorbed onto a flat surface will have a single neighbouring atom, whereas an adatom absorbed at a step site will have two. By this logic the absorption energy at the step site will be twice that of the planar surface, making binding far more probable at these locations. Under conditions where nucleation due to monomer collisions is unlikely, nucleation at step and kink sites becomes an important process and may be key in defining the structure (and growth rate) of the completed films.

Post-Nucleation Growth Phase

This Section describes in detail the individual processes of film development that follow nucleation according to the scheme outlined above. Other alternatives are possible, but for the CdTe material system explored in this detailed description, film growth by the island mechanism is most relevant. The description is ordered according to the development of the film. First the growth of nuclei to form islands is discussed, including the addition processes that take place on crystalline facets. Next, the coalescence of islands is described, this taking place by a variety of possible mechanisms including Ostwald ripening, by the motion of islands and by a simple growth mechanism. Finally, the processes by which a film comprising of islands is developed into a film with complete surface coverage are described. At this point the conditions required for channel formation and secondary nucleation are considered.

Island Growth and Capture Zone

After nucleation, islands will increase in size by further addition of adatom species. This may occur by two means, i) by adatoms impinging directly onto islands from the vapour phase and ii) by surface diffusion of adsorbed species. In the case of total substrate coverage, growth must take place solely by direct impingement but, in the instance of small island size and low coverage, surface diffusion is likely to be the dominant process. Any adatom incident within a certain distance (δ) of an existing island is assumed to diffuse toward the island and be captured by it. The size of the capture zone is of the order of the average adatom diffusion distance, and will hence also depend on the surface diffusion and adatom lifetime via the relation¹⁸;

δ≈\sqrt{Dₛτₛ} (0.17)

The capture zone width is therefore related to the mean adatom diffusion distance X (equation 0.14), by δ≈\sqrt{2}X. The rate at which islands grow will be dependant on the surface diffusion coefficient, as well as the impingent rate of new monomers onto the surface. As any adatom within this region is assumed to be captured, the region can also be considered as a nucleation exclusion zone (since the local surface occupancy is reduced, the probability of collisions generating nuclei r>r* is reduced).As island growth progresses, the surface area covered by islands and their associated exclusion zones will increase, reducing the probability of new nucleation. After a certain amount of growth no subsequent nucleation becomes possible, as all adatoms incident on the surface will be incorporated into existing islands. Nucleation then ceases and a secondary bout of nucleation may only occur at a later stage of growth after the dynamics of the island distribution have been altered by coalescence effects.

Step Flow Processes and Facet Formation

Polycrystalline thin films often exhibit visible grain structure with smooth crystal facets being apparent. Formation of these facets is indicative of uninterrupted step flow within the growing film.

At an atomic level a smooth surface is not truly flat but will rather take the form of an ordered series of terraces, as shown in FIG. 5b, giving the illusion of a smooth surface. In order for flat facets to be produced it is essential these steps form without inhibition. FIG. 5a shows the addition of surface species to a terrace and binding at a step. By continued addition to this step, the step may be considered to propagate along the surface, a process known as ‘step flow’.

Disruption of the step flow process will lead to rounding of the grains. Such grains are typically formed due to low mobility of surface species resulting from low deposition temperatures. However, polycrystalline films can develop rounded grains as a result of the co-deposition of impurity species, especially oxygen on account of its reactivity. Impurities may gather at the steps disrupting the step flow, and consequently the formation of singular crystal facets is inhibited. Although the above description is presented as part of a narrative of nucleation events, it is the case that surface processes on the film material itself shall be important at all stages of thin film formation and not exclusively during nucleation.

Coalescence of Growth Islands

Coalescence is the processes by which two previously separate islands merge together, reducing the total surface area of islands and their coverage of the substrate. Coalescence may be divided into two forms: i) incomplete, where a grain boundary remains incorporated, or ii) complete, liquid-like coalescence where the merged islands re-order to form a single island. In the latter the two islands may behave as two liquid droplets merging together to form a single droplet before re-crystallising as a single island. While this seems strange behaviour for solid islands on a surface it has been demonstrated by various groups using in-situ techniques and explained in terms of sintering and neck formation. The occurrence of liquid-like behaviour depends explicitly on the size of islands: there is a critical size for a given set of conditions, below which they may behave in a liquid-like manner. Above this size however, they will remain solid during coalescence and complete coalescence will not occur unless by another mechanism.

This section shall concentrate on the various modes by which coalescence may occur such as Ostwald ripening, coalescence by cluster mobility and coalescence by growth.

a) Ostwald Ripening

In Ostwald ripening larger islands are assumed to grow at the expense of nearby smaller islands, as they are favoured energetically and more stable due to their larger surface area. In the case of close-space sublimation or vacuum evaporation, Ostwald ripening occurs due to the difference in the vapour pressures of large and small islands, with smaller islands having a higher vapour pressure. The smaller islands are therefore more likely to dissolve and be absorbed by the larger islands than to continue to grow. However, in thin film growth Ostwald ripening is more important during post growth annealing rather than deposition as it is a slow processes in comparison to the typically rapid deposition of thin films.

b) Coalescence Due to Island Motion

Islands formed on a surface are not necessarily static, and due to high substrate temperatures clusters may be mobile. Their level of mobility will depend on cluster size, with smaller clusters being more mobile. Coalescence may occur by islands meeting due to migration across the surface Small crystallites can be seen to move across the surface before colliding with other particles and engaging in liquid-like coalescence. The process is not limited to small aggregates of a few atoms in size, larger islands with distinct crystal facets are also mobile on the surface. This is however unlikely to be the dominant mode of coalescence in thin film formation, due to the relatively slow nature of the process compared with the time required to form a complete film.

c) Coalescence by Growth Mechanism

Assumed to be the dominant coalescence process in thin film formation, coalescence by growth occurs when islands come into contact with one another as they increase in size. Islands may initially be well spaced due to capture zones surrounding the islands, but as the growth progresses the islands will increase in size, the capture zones will overlap and the islands will eventually touch. Islands may then coalesce rapidly in an apparently liquid-like manner to form a single island.

The principal driving force behind coalescence is lowering the surface energy by reduction of the combined surface area of the constituent islands. If two islands with distinct orientations grow until they come into close proximity, a neck begins to form in the region between the two islands. This neck formation process can be attributed to rapid surface self diffusion of material from the islands. The surface energy of the composite is quickly reduced during the initial stages of coalescence by rounding of the edges of the islands. Material from regions furthest from the neck is transferred to the neck, causing it to thicken at the join between the two islands. The islands may eventually lose their crystal habit planes as a result of this process. The surface energy is then minimised by reformation of a crystallographically shaped island from the composite. It is generally accepted that if islands of two different orientations coalesce, then the resulting crystallographic orientation will be that of the larger of the two islands. Coalescence in this manner reduces the density of islands on the surface.

The rate at which islands coalesce will be dependant on the size of islands, with smaller islands coalescing much more rapidly than larger ones—due to the faster rate of neck formation. Eventually the rate of coalescence will become so slow for large islands so as to not fully complete before further addition of adatoms causes a significant increase in the size of the coalescing islands. Coalescence remains incomplete and leads to the process of channel formation.

Formation of a Complete Film

A complete film is often not comprised solely of islands formed at the beginning of film deposition. Primary islands may coalesce and leave vacant channels, with the gaps being filled by secondary nucleation to produce a continuous film.

Channel Formation

Complete island coalescence will not continue indefinitely up to the formation of a complete film but will instead reach a limit as the composite islands reach a certain size. As island size increases, complete coalescence becomes improbable due to the relatively slow rate of the process at these sizes. It has been shown that the required time to produce a neck between two islands was proportional to the fourth power of the initial radius of the coalescing islands. Therefore for large island sizes the rate of addition to the composite island from species on the surface may be greater than the rate of material transfer between the coalescing islands. Islands size therefore increases at a greater rate than coalescence progresses and the time required for coalescence increases as the process continues. Neck formation will not complete and the islands will take on an elongated shape leading to the definition of channels between the islands (FIG. 3e). The size at which islands will begin to behave in this manner is linked to the diffusion rate of species on the surface, and hence the substrate temperature. In the instance of high surface diffusion rates (high substrate temperature), complete coalescence will occur for relatively large island sizes as the rate of material transfer between islands is high, while the adatom lifetime on the surface is low. An increased substrate temperature therefore increases the rate at which coalescence progresses, while slowing the rate of addition of further species to the coalescing island pair by reducing the adatom lifetime. Like the majority of surface processes involved in thin film formation, the occurrence of channel formation is dependant on the deposition conditions for film growth. In conditions where the rate of coalescence is low, channel formation may be expected to occur for significantly smaller island sizes than in other regimes where coalescence occurs at a more rapid rate.

Secondary Nucleation and Complete Film Formation

The channel formation stage leaves gaps in the material that are filled by secondary nucleation. This will eventually lead to the formation a continuous film. Coalescence of islands reduces the combined surface area of the constituent islands and serves to reduce the overall coverage of the surface. During coalescence an area of the substrate previously occupied by islands (and their capture zones) will be revealed. This area therefore becomes available for nucleation. Secondary nucleation of islands may therefore occur in the channels formed by the coalescence of primary islands. Because these new islands are small, in comparison to the initial islands, they rapidly coalesce by the mechanism described above. They are then incorporated into the bulk of the material as they grow and come into contact with the sides of the channels. As growth continues the majority of channels are eliminated, leaving only a few small irregularly shaped holes. Subsequent nucleation will then fill these holes and the resulting islands will become incorporated into the bulk. This leads to the formation of a continuous, hole free, film.

Although the proceeding is an account of secondary nucleation events encountered during channel filling, it is likely that secondary nucleation occurs throughout growth as a result of coalescence events. However, it is only at this stage that nuclei grow to super-critical sizes and are as such stable.

Growth of CdTe Thin Films on CdS

CdTe thin films, deposited on CdS/ITO/glass, constitute the superstrate device configuration regularly employed in CdTe/CdS solar cells. Study of the formation process of CdTe thin films deposited upon CdS is therefore of direct relevance to solar cell device fabrication.

Sample Fabrication

CdS thin films were deposited by CSS onto ITO/glass substrates bought from Vision Tech Ltd. Substrates were cleaned prior to CdS deposition by ultrasonication in Decon 90, water, acetone then isopropanol. CdS films were deposited in vacuum at constant source and substrate temperatures of 650° C. and 540° C. respectively. The growth time was 2 min, which produced CdS layers of ˜300nm thickness. The substrates were 5×5 cm in size but were broken in 2.5×2.5 cm quarters after CdS deposition. This was done to reduce the number of CdS growth runs required, and to minimise any systematic error due to variation in the growth of the CdS layers. CdTe films were deposited on top of the CdS layer at constant source and substrate temperatures of 600° C. and 500° C. respectively. A chamber pressure of 100 Torr was used, as this resulted in quicker deposition than at 200 Torr (as used previously been used).

Growth in a Nitrogen Ambient

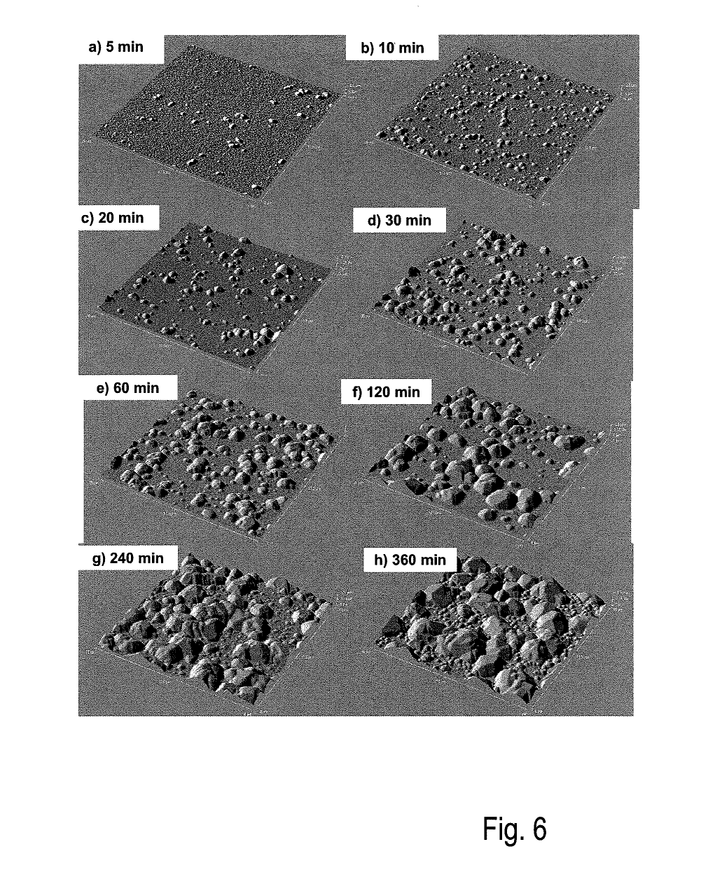

A series of CdTe thin films were grown for a various times in the range 5-360 min in a nitrogen ambient, at a pressure of 100 Torr. Samples were grown out of sequence to avoid any systematic error. FIG. 6 shows AFM images of the series. The development of CdTe island structures can be clearly seen from the AFM images of the samples. Nucleation occurs via the Volmer-Weber mode of growth.

At the earliest stage of growth examined, t=5 min (FIG. 6a), nucleation has occurred by the formation of a number of small well spaced islands on the surface at a density of 0.08 μm-2 and with an average area of 0.78 nm2. By t=10 min (FIG. 6b), the island density has increased dramatically (FIG. 6c) indicating that nucleation has continued in the preceding period. Individual islands grow continually throughout this period by further addition of species diffusing across the surface. Despite this however, the average island area has decreased slightly over this period (FIG. 6a), due to the formation of a large number of new, smaller, islands which act to reduce the average size. Substrate coverage more than doubles during this period (FIG. 6b), increasing from 6% to 14%.

At t=10 min, the island density is at a peak for the period studied, while the average area is at a minimum. This point may be considered as the end of the initial nucleation period (as discernable from the growth times chosen for this experiment). At this point a network of stable islands has been established on the substrate and these islands proceed to grow by further addition of species at the expense of any further nucleation occurring. No further nucleation is observed to occur during this period, by either SEM or AFM analysis. Hence, for the period of growth succeeding this, 10 min<t≦120 min (FIG. 6c-f), the island density continually decreases while the average island area increases.

Due to their increase in size, islands come into contact and undergo complete coalescence (re-ordering as a single island) and this reduces the island density. By the end of this period, t=120 min (FIG. 6f), island density has significantly reduced. Islands are now relatively large as a result of coalescence and continued growth, while some have begun to take on an elongated shape as a result of coalescence. This is an indication that islands have reached a large enough size so as to make complete coalescence improbable due to the long times required for neck formation to progress. This is the beginning of the channel formation stage.

At t=240 min (FIG. 6g), the formation of channels can be seen more clearly. Primary islands have formed a coalesced network, leaving vacant channels between.

Secondary nucleation of islands begins to occur in the channels, leading to an increase in the island density. Whilst islands do continue to grow by further addition of adatoms, the increase in average area shown in FIG. 6a is relatively small. This occurs due to the onset of secondary nucleation introducing a number of smaller islands, rather than any change in island growth rate.

For the final growth monitoring time, t=360 min (FIG. 6h), the size of the networked primary islands has increased while secondary nucleation has continued in the channels. The island density has increased but the average area has reduced, due to the occurrence of these secondary islands. At this final monitoring stage, coverage is reasonably high (˜70%). Formation of a complete film is expected to occur at growth times significantly longer than were employed here. The manner of film completion is expected to be by growth of secondary islands, their incorporation into the network of primary islands and a final bout of nucleation to fill any remaining gaps.

Plotting the data for average island aspect ratio (width/height) and average layer thickness shows that, while layer thickness increases throughout growth there is little variation in the aspect ratio, implying that growth in the horizontal and vertical directions is balanced. Therefore, islands maintain their initial dimensions during growth and coalescence and the island contact angle remains relatively constant throughout growth.

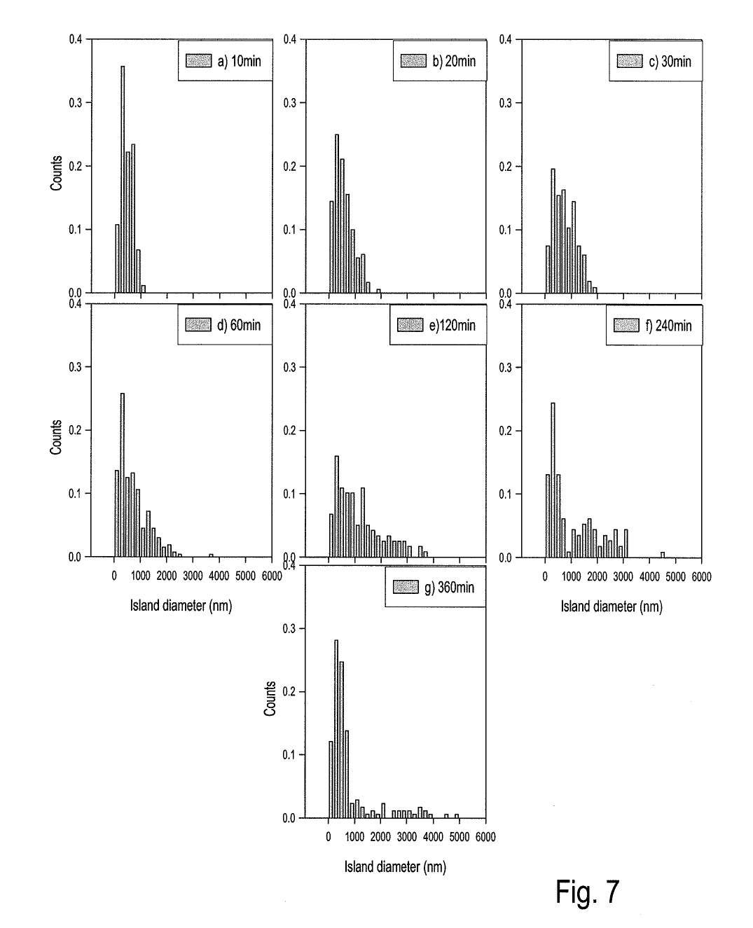

As well as the average values for island size, significant information may be extracted from the distribution of island sizes and its progression with time. FIG. 7 shows the normalised island diameter distribution plotted as a function of growth time. Diameters were determined from AFM images of films shown in FIG. 6. Data from the t=5 min sample is not included, due to the small number of observed islands. Diameter values were calculated from an equivalent circle based on the island area using the equation;

$$D = 2 \sqrt{\frac{A}{π}}$$

where D is the diameter of the equivalent circle and A is the island area, determined by AFM analysis. Due to the various processes involved in thin film growth that may alter the size distribution of islands (e.g. coalescence, secondary nucleation), successful fitting to a Gaussian distribution is unlikely (The possible exceptions to this are at very early stages of growth, before coalescence effects begin to occur, and after the film has formed a complete layer). Instead, Rayleigh distributions have been successfully fitted to grain size distributions in complete CdTe thin films. For the early stages of growth examined in this work (10 min≦t≦20 min), the histograms are approximated by a Gaussian distribution. As the growth progresses and coalescence processes begin to dominate, this Gaussian character is lost and secondary peaks at larger island diameters begin to appear.

This can be most clearly seen at t=240 min, where the histogram has a well defined minimum for an island diameter of ˜900 nm. The appearance of this double peaked distribution provides an indication of the mode of coalescence prevalent during growth. The dominant coalescence mechanism will influence the size distributions of stable islands.

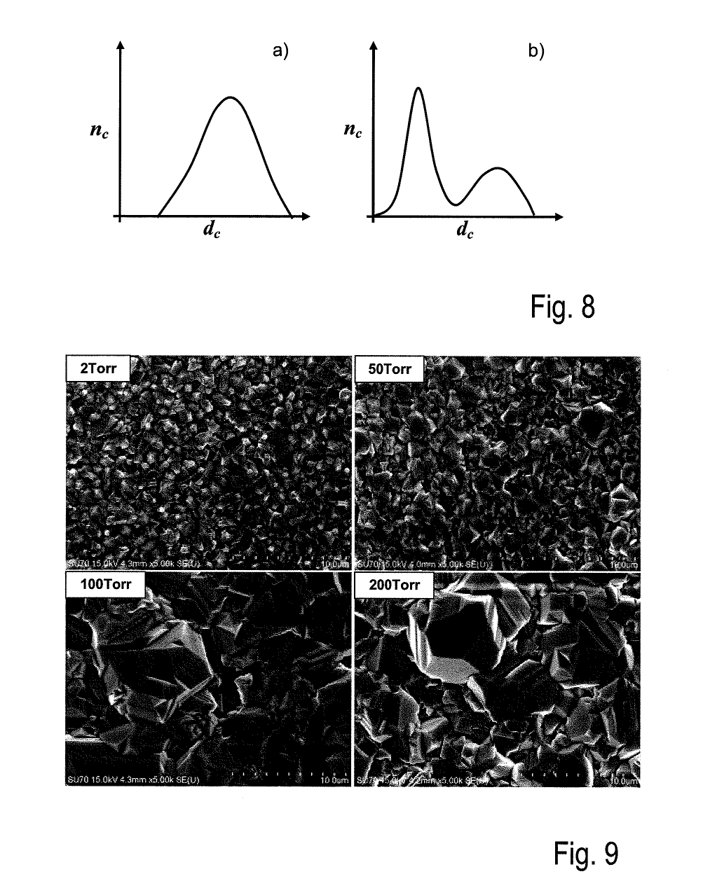

FIG. 8 shows the schematic histograms for the cases of: a) coalescence via island mobility and b) coalescence by island growth. The distributions are assumed to be Gaussian prior to the onset of any coalescence effects. In the instance of coalescence by island mobility, smaller islands are more mobile on the surface than larger islands and therefore more likely to be involved in coalescence interactions. This produces a shift in the whole distribution towards the larger cluster diameters and results in the distribution seen in FIG. 8a. For coalescence by growth it is the larger islands that are more likely to undergo coalescence, as they are more likely to come into contact with neighbouring islands due to their increased size. The distribution therefore spits into a double peak (FIG. 8b), as the large islands in the initial distribution coalesce and then re-order to form yet larger islands than those present in the initial distribution. The island distributions observed here for CdTe thin film formation indicate that coalescence occurs by island growth (yielding double peaked distributions), with no evidence for coalescence by island mobility being observed.

Influence of Nitrogen Pressure on CdTe Growth and Device Performance

Now that the mechanism for layer deposition is understood, and in particular for CSS CdTe deposition, it is now possible to explain the surprising effects, realised by the inventors, of the ambient pressure (in this case nitrogen) on grain size. The following describes the effect of nitrogen pressure on the CdTe grain structure in completed CdTe/CdS devices, along with its effect on device performance, as discovered by the inventors.

Cell Fabrication Conditions

A series of four devices, with CdTe layers deposited under different pressures of nitrogen, were fabricated using commercial FTO Tec8 substrates (2.5×2.5 cm). 150 nm thick CdS films were deposited by CSS under 2 Torr of oxygen at source and substrate temperatures of 650° C. and 520° C. respectively. Prior to CdTe deposition the CdS films were annealed under 3 Torr of hydrogen, at a temperature of 400° C., for a period of 2 mins in the CdTe deposition chamber. CdTe films were deposited by CSS under various pressure of nitrogen (2, 50, 100 and 200 Torr), at source and substrate temperatures of 600° C. and 460° C. respectively, with a layer thickness of ˜8 μm for all devices. Due to the sublimation rate being reduced with increased pressures the CdTe deposition time had to be varied in order to generate equal layer thickness for each pressure, with deposition time being 2 min for 2 Torr and 90 min for 200 Torr. After CdTe deposition a 200 nm CdCl2 layer was deposited on the CdTe back surface before cells were subjected to annealing in air at a temperature of 400° C., with the treatment time being optimized for each device (in the range 5-20 min). The cells were then subjected to a 10 s NP etch, before a series (˜25) of 2 mm diameter circular gold back contacts were applied by vacuum evaporation.

Scanning Electron Microscopy (SEM) and Atomic Force Microscopy (AFM) Analysis of Grain Morphology

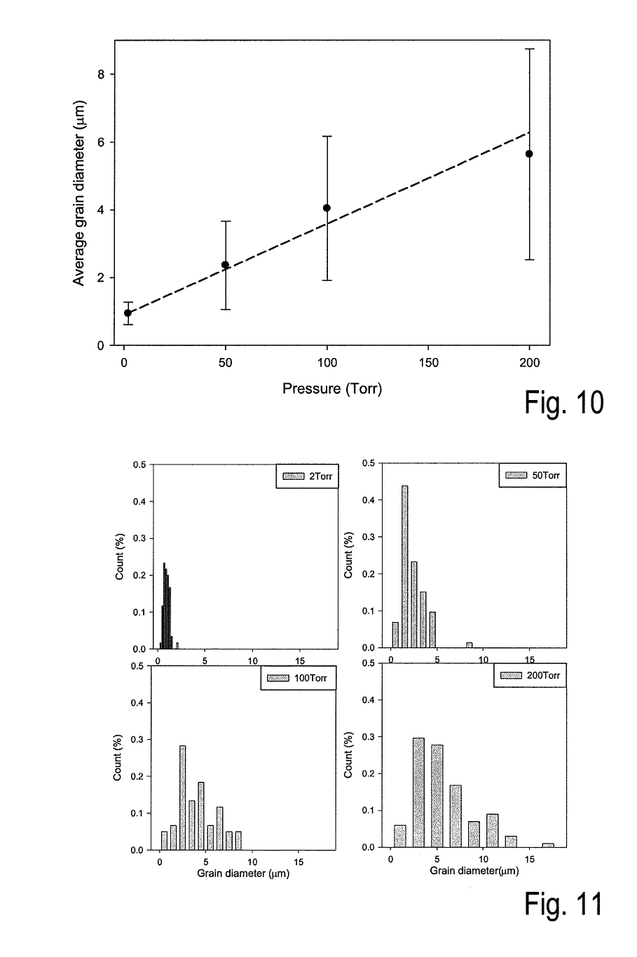

FIG. 9 shows SEM images of the CdTe films deposited under pressures of nitrogen in the range 2-200 Torr. Grain radius values were determined by manual measurement from SEM images, with the average grain radius (being determined from the measurement of 100 individual grains) plotted against deposition pressure in the graph of FIG. 10, whilst histograms of grain size for the various pressures are shown in FIG. 11.

It can be clearly seen from the SEM images in FIG. 9 that the change in deposition pressure has had a dramatic effect on the grain structure of the deposited CdTe films. The grain size is noticeably larger in the films deposited under higher pressure, as shown in the graph of average grain size (FIG. 10—note that the linear fit R=mP+c is subject to considerable uncertainty. The best fit and the associated error in the gradient and intercept values were determined using the χ2+1 method. The determined values were m=0.27+/−0.11 and c=0.90+/−0.31) and the histogram distributions (FIG. 11). For the lowest deposition pressure used (2 Torr) the average grain diameter was relatively small, 0.94 μm, whilst the maximum diameter observed was only 2.01 μm. As the pressure was increased the typical grain diameter became larger, average values being 2.36 μm for 50 Torr, 4.04 μm for 100 Torr, reaching an average of 5.63 μm and a peak of 17.60 μm for a pressure of 200 Torr. As can also be seen from the histograms in FIG. 11 the range of grain sizes observed at high pressure was also increased with there still being a number of smaller grains (˜1-2 μm). All films displayed well defined crystal facets, regardless of the deposition pressure.

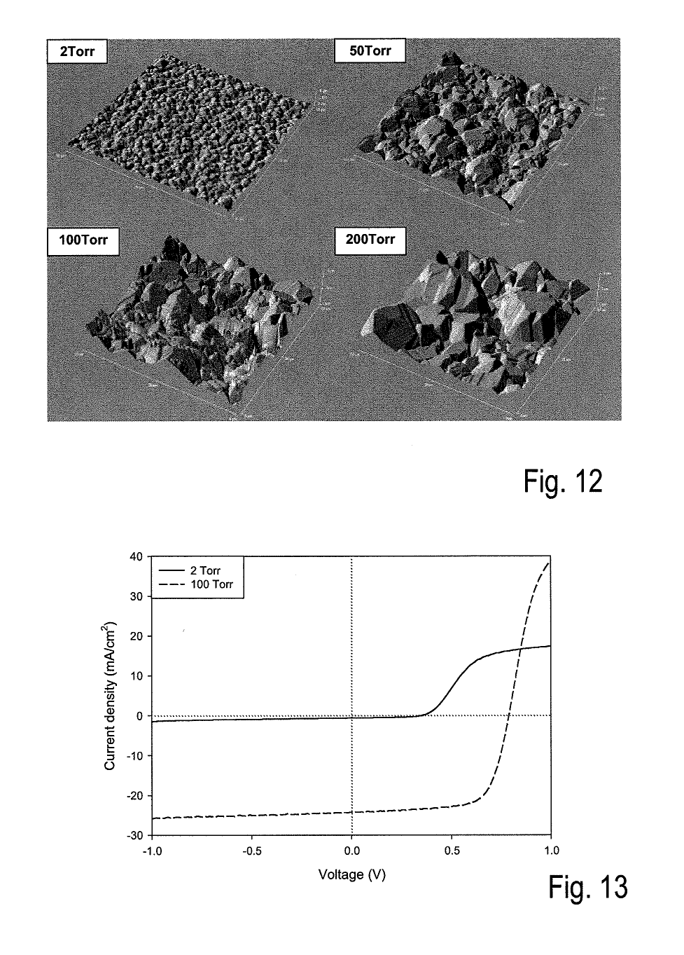

In addition to the SEM investigation (and extraction of grain size information) above, an AFM investigation of the same samples was undertaken, the results being shown in FIG. 12. All images have the same Z-axis scale, so as to allow direct comparison of the change in the layer microstructure. These images confirm the findings of the SEM measurements, emphasising the increased grain size for higher deposition pressures. The roughness and height range of the samples has also visibly increased, with the film deposited at 2 Torr appearing relatively flat in comparison to the large peaks and troughs displayed in the other films. Roughness and height range values determined from these measurements reveal that the average roughness increases from 236.1 nm (2 Torr) to 965.1 nm (200 Torr), with the maximum height range of the films increases from 2.58 μm (2 Torr) to 7.07 μm (200 Torr).

J-V and EQE Analysis

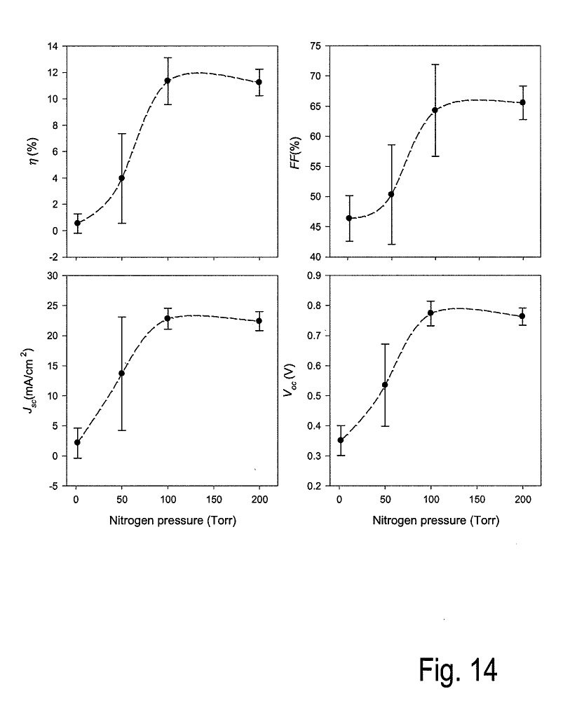

J-V curves were recorded under AM1.5 illumination for all back contacts from each device (i.e. ˜25 J-V measurements for each deposition pressure used). Typical J-V curves for samples with CdTe layers deposited under 2 and 200 Torr nitrogen pressures are shown in FIG. 13, while extracted device parameters η, FF, Voc and FF are plotted for all contacts as a function of pressure in FIG. 14.

The J-V (current density -voltage) curves reveal a gulf in performance between the devices deposited at low (2 Totrr) and high (100 Torr) pressures. The device deposited at higher pressure shows an obvious improvement in both the level of current generated in reverse bias and the open circuit voltage of the device. The device deposited at 2 Torr also shows a large degree of rollover in forward bias. Although not immediately apparent from the J-V curves due to the scaling of the plots, both curves show similar gradients under the reverse bias implying little variation in the shunt resistance of the devices (see Section 2.3). However, there is significant change in the gradients of the curves under forward bias (the roll-over portion of the 2 Torr curve is not considered), with the 200 Torr device showing a steeper gradient, indication of a reduced series resistance.

The extracted performance parameters shown in FIG. 14 highlight the variation in performance further, revealing the device efficiency to increase from an average 0.54% (peak of 2.12%) at 2 Torr to an average of 11.34% (peak of 13.17%) at 100 Torr. All device parameters are seen to increase in accordance with the increase in efficiency, with there being a notably large change in the average Jsc (short circuit current density) (2.17 mA/cm2 at 2 Torr to 22.80 mA/cm2 at 100 Torr). Of particular note however, is the change in the device Voc (open circuit voltage) with increased pressure, with the average Voc being found to increase from 0.35V (peak of 0.44V) at 2 Torr to 0.77V (peak of 0.80V) for a deposition pressure of 100 Torr. Whilst equivalent levels for the short circuit current were found to be attainable by other methods (i.e. CdTe deposition under 2 Torr of oxygen yielded Jsc values in the 20-25 mA/cm2 range, see Section 8.3), the Voc values obtained for higher pressure depositions were significantly greater, with the best Voc obtained for a device deposited under a “normal” deposition pressure (i.e. in the range 0-5 Torr) being 0.68V.

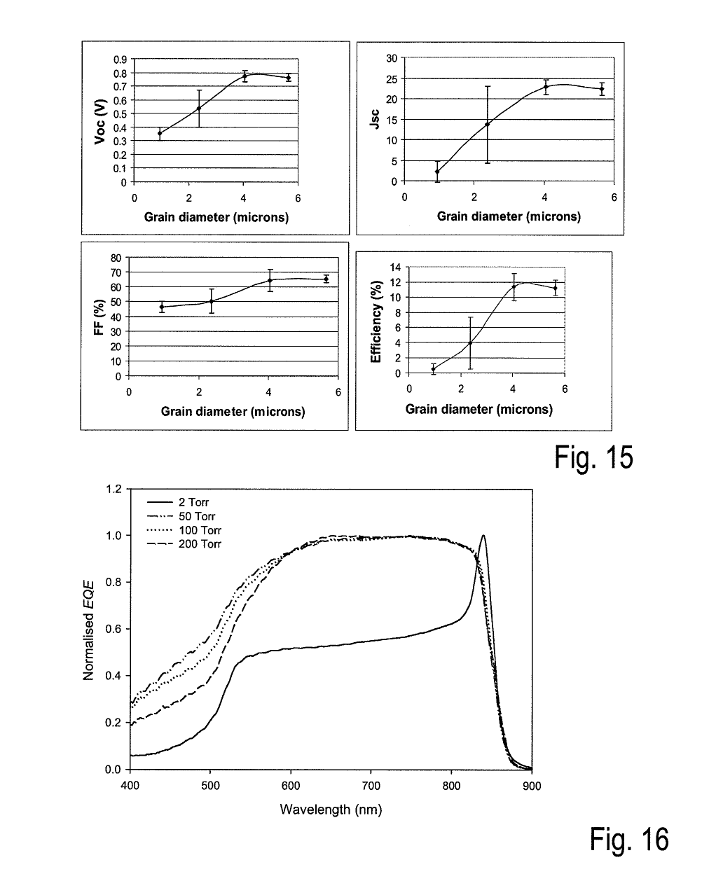

FIG. 15 shows the above cell performance parameters re-plotted as a function of grain size rather than pressure, to show that it is the increase in grain size which results in the above improvements.

FIG. 16 shows normalised EQE (external quantum efficiency) curves taken from a representative contact for devices deposited under each nitrogen pressure. The cell with CdTe deposited under 2 Torr of nitrogen shows the characteristic shape of a buried homo-junction, providing an explanation for the poor performance of the device. Cells deposited at higher pressures (50-200 Torr) all display a more typical hetero-junction shape, with a uniform response in the 520-840 nm range. There is little variation observed in the shape of the EQE curves between these higher pressure devices, except for in the 400-520 nm region, which can be attributed to variation in the CdS thickness. There is also a slight change in the EQE within the 520-600 nm region, indicating a variation in the level of intermixing, however no associated shift of the CdTe cutoff (˜845 nm) is observed. Any change in the level of intermixing level has therefore had little effect on the CdTe bandgap.

The above shows that by utilizing higher than normal nitrogen pressures during

CSS deposition, a notable increase in the grain size of CdTe films has been achieved. From a consideration of the mechanism of nucleation and growth for a polycrystalline film (explained above) it appears that an increase in pressure induces a change in the arrival rate of adatoms at the surface, with the rate being reduced for higher pressure. Even though the adatom surface lifetime is expected to be unaltered by pressure, the adatom surface population is nevertheless reduced, hence diminishing the probability of stable nuclei being formed. This leads to a smaller number density of islands being formed, meaning that islands grow to larger sizes, resulting in a film with a larger grain size.

Therefore, to summarise the above findings, growth of CdTe onto thin film CdS by ‘close space sublimation’ in a series in which only the pressure of nitrogen gas was intentionally varied, yielded a profound increase in the average grain size of the CdTe. Increasing the pressure from 2 to 200 torr gave an increase over the full range from ˜1 to ˜6 μm. This is contrary to the published literature in which the same behaviour is not observed

Very little work has previously been reported on the effect of CSS deposition pressure upon CdTe film microstructure. What work had been done suggested that grain size could be adversely affected by higher pressures. V D Falcao, et al in their paper: Influence of deposition parameters on the properties of CdTe films deposited by close spaced sublimation (Materials Research 9 (1) 2006 29-32) reported a small increase in grain size (0.92-1.64 μm) upon using argon pressures of up to 10 Torr, but they concluded that at pressures above 10 Torr no further size increase could be achieved, and in fact grain size decreased at 20 Torr. Similarly, O Zelaya, et al in Large grain size CdTe films grown on glass substrates (J Appl Phys 63 (2) 1988 410-413) grew CdTe by sublimation onto glass. They concluded that grain size was dependent on ambient Argon pressure in the range 0.5-100 torr. However, they observed a peak at between 1 and 10 torr.

The results presented in this chapter contradict these findings, demonstrating the grain size continually increased for nitrogen deposition pressures of up to 200 Torr.

It should also be noted that the above discussion does not necessarily indicate the upper limit of grain size. It does seem probable that use of pressures >200 Torr may result in even larger grain sizes.

Furthermore, the grain size achievable may not be limited by the deposition pressure, but rather by the nature of the deposition surface. Under extremely high pressure conditions, nucleation as a result of adatom surface collisions may no longer occur due to the low adatom surface occupancy. However, nucleation at surface defect sites (e.g. kinks, steps) may still occur due to the increased absorption energy at these locations. In this case the minimum density of nucleation occurring, and by extension the maximal grain size, will be dependant upon the density of these defect locations and hence the substrate.

X-Ray Diffraction (XRD) analysis of the CdTe films reveals a decrease in the level of preferred orientation with increased grain size. The layer deposited at 2 Torr was found to be strongly [111] oriented, with other orientations becoming more pronounced as the deposition pressure was increased. Other publications have reported results somewhat contrary to this, with films becoming more strongly [111] oriented with increased grain size, albeit due to higher substrate temperatures used during deposition. This discrepancy may be explained in terms of adatom surface processes as follows: in both instances (i.e. increased substrate temperature and increased deposition pressure) the increase in grain size is believed to be caused by a reduced nucleation density, resulting from a decreased adatom surface occupancy. In the case of deposition with increased substrate temperature (with the source temperature being constant), the surface occupancy is reduced due to a higher rate of adatom re-evaporation from the surface, as a consequence of a shorter adatom surface lifetime. Whilst this serves to diminish the possibility of nucleation occurring via adatom surface collisions, the rate of addition to existing stable nuclei will be uninhibited, as the arrival of further species from the vapour beam remains constant. The rate of addition of adatoms to existing island may in fact be expected to increase, as the adatom surface mobility is greater for higher temperature. By raising the substrate temperature during film deposition, the growth rate of individual islands may be increased.

For deposition using higher nitrogen pressure, the reduction in adatom surface population has been achieved by slowing the rate adatoms arrive at the surface, by limiting sublimation from the source. Therefore, the inventors realise, the rate at which individual islands grow is reduced for deposition under a higher pressure. In terms of the development rate of individual islands, increasing the deposition pressure is therefore akin to decreasing the substrate temperature and it appears to be this rate of island development that determines the orientation of the film. CdTe films in which the islands develop at a fast rate are more prone to developing [111] orientation, whilst reducing the rate of development leads to other orientations being observed.

Device performance was found by the inventors to improve significantly for deposition under higher pressures, with the efficiency reaching a peak of 13.17% at 100 Torr. However, further refinement of the CdCl₂ treatment step led to efficiencies of up to 14.1% being achieved for deposition under 100 Torr. The device performance was found to remain reasonably constant for 100 and 200 Torr pressures, despite there being a significant increase in grain size (average 4.0-5.6 μm) for the 200 Torr device. This indicates that the influence of any grain boundary effects, upon the device performance, was relatively small. However, the device with the CdTe layer deposited at 200 Torr, whilst not showing any improvement in the level of response, did display less contact to contact efficiency variation (this may be seen in FIG. 8.22). It is therefore expected that for larger back contact sizes, CdTe deposition at 200 Torr may yield better device results due to an overall improvement in the uniformity of the CdTe layer.

The inventors have also realised that CdTe deposition at higher nitrogen pressures (≧50 Torr) leads to the formation of a CdTe/CdS hetero-junction, whilst deposition at a more standard (2 Torr) pressure leads to the formation of a CdTe homo-junction. It has been shown by the inventors that the formation of a CdTe homo-junction was due to the lack of oxygen during CdTe deposition of these cells, whether from the deposition ambient or the CdS layer (in the case of deposition on CBD CdS). Whilst no oxygen was included during CdTe deposition, the CdS layer was deposited in the presence of oxygen. It may be possible that the longer deposition times required for higher pressure depositions (40 min at 100 Torr, 90 min at 200 Torr) may act as an anneal of the CdTe/CdS structure, allowing oxygen diffusion from the CdS to the CdTe layer, thus providing p-type doping. This suggests that the homo-junction formation may be corrected for by annealing at deposition level temperatures, after deposition has been carried out.

In order to identify the means by which the process is effective in improving the performance of solar cells, the inventors have undertaken some fundamental studies. AC methods have been used to resolve the impedance contributions of various parts of the solar cells. These indicate that for the cells tested, the grain boundary component to resistance dominates for low grain sizes, but does not for higher grain sizes: Then the contributions from for example, the junction and the contacts may dominate. We expect that for solar cells in which the contacts and junction have been fully optimised, the balance of the contributions may differ. It is therefore not possible to specify a minimum grain size threshold for optimised devices, but for these devices it appears to be about 4 μm.

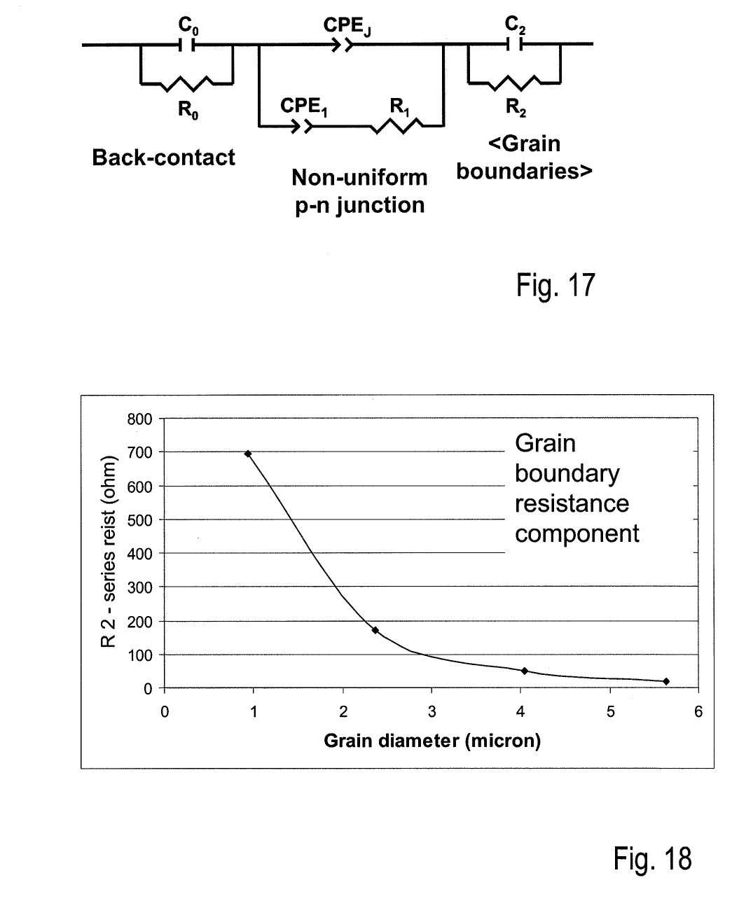

Other mechanisms may also be responsible for the improvements arising from the process. However, at present it is believed that the model given in FIG. 17 represents the electrical performance of the cell. Also, it is not excluded that there may be other benefits from the above process, e.g. increased devices stability and device yield.

It was found that the contacts contributed 100±40Ω, the junction 40±20Ω and the grains, as per FIG. 18. For these cells, the grain boundary resistance dominates over the other contributions until the grain size exceeds about 4 μm. It is expected that by improving both the junction and the contacts using already published methods, it shall be possible to achieve exceptional solar cell performance, yield and stability.

Consequently, it is expected that by combining the process for obtaining large grains with already published means for improving the other parts of the cell, it is possible to obtain cells with higher performance than has been demonstrated herein.

One drawback of the above processes is that they suffer from the rate of growth being slowed substantially. Growth of a thickness suitable for solar cells may for example take 60 minutes rather than less than 10 minutes. Consequently an improvement to the above methods, to yield faster growth times, would be desirable. One solution to this would be to switch the pressure during growth, for example by means of the sample progressing through more than one space or chamber, or by pumping. For example the growth could be started at high pressure so as to nucleate large grains, followed by continuation at lower pressure, either stepwise or ramped.

Another possibility to address the growth rate issue is to change the gas used in the processing, for example from a high molecular weight to a low molecular weight gas. The inventors, for example, performed similar experiments wherein a 1% partial pressure of hydrogen (99% N2+1% H2) was included in the processing ambient. This resulted in a significantly increased Island density n comparison to growth in a pure nitrogen ambient. Complete substrate coverage was achieved after a much shorter growth time—this being 90 min for growth in a hydrogen containing ambient, while coverage was only 70% after 360 min growth in a pure nitrogen ambient. Secondary nucleation also occurred at a much earlier time, and more extensively than in the case of a pure nitrogen ambient. This change of ambient gas may be done during the process, for example, introducing a lower molecular weight gas or, progressing the sample to a chamber with different ambient gas, after a number of minutes have passed.

It is submitted that the detailed example above is for illustration only and other embodiments and variations fall within the spirit and scope of the invention. Most notably other sublimation methods may be used, as may other materials.

1. A method of depositing a film of a first material on to a second material by a physical vapour deposition process wherein said deposition is performed in an atmosphere having a relatively high ambient pressure.

2. A method as claimed in claim 1 wherein said relatively high pressure is 20 Torr or more.

3. A method as claimed in claim 1 wherein said relatively high pressure is 50 Torr or more.

4. A method as claimed in claim 3 wherein said relatively high pressure is in a range between 50 Torr and 200 Torr.

5. A method as claimed in claim 1 wherein said relatively high pressure is in the order of magnitude of 100 Torr.

6. A method as claimed in claim 1 wherein said physical vapour deposition process is any such growth mechanism based on sublimation transfer.

7. A method as claimed in claim 6 wherein said physical vapour deposition process is close-space sublimation.

8. A method as claimed in claim 1 wherein said atmosphere comprises a substantially pure inert gas.

9. A method as claimed in claim 8 wherein said gas is Nitrogen.

10. A method as claimed in claim 1 wherein said gas is a gas of low molecular weight.

11. A method as claimed in claim 10 wherein said gas comprises hydrogen, helium, or a mixture of either (or both) with nitrogen.

12. A method as claimed claim 1 wherein said method takes place in a deposition chamber, said relatively high ambient pressure being the pressure in said deposition chamber.

13. A method as claimed in claim 1 wherein said method is used in the manufacture of solar cells.

14. A method as claimed in claim 1 wherein said first material is a semiconductor material.

15. A method as claimed in claim 14 wherein said first material is Cadmium Telluride and said second material is Cadmium Sulphide.

16. A method as claimed in claim 1 wherein including the step of varying the ambient pressure during the deposition process.

17. A method as claimed in claim 16 wherein said method is begun at said relatively high ambient pressure to nucleate large grains, the pressure being subsequently lowered to speed up deposition.

18. A method as claimed in claim 17 wherein said lowering of pressure is done once.

19. A method as claimed in claim 17 wherein said lowering of pressure is done a plurality of times in a stepwise fashion.

20. A method as claimed in claim 17 wherein said pressure is continuously lowered in a ramped fashion. In the latter two cases.

21. A method as claimed in claim 19 wherein said lowering of the pressure is done throughout the deposition process.

22. A method as claimed in claim 19 wherein said lowering of the pressure is done during a portion of the deposition process.

23. A method as claimed in claim 22 wherein said lowering of pressure is begun only after a predetermined interval.

24. A method as claimed in claim 17 wherein said lowering of the pressure is achieved by pumping.

25. A method as claimed in claim 17 wherein said lowering of the pressure is achieved by moving the sample through more than one space or chamber, each of which having different ambient pressures.
